(19) United States
(12) Patent Application Publication
(10) Pub. No.: US 2020/0161392 A1
(43) Pub. Date: May 21, 2020

(54) ORGANIC LIGHT EMITTING DIODE DISPLAY AND METHOD FOR MANUFACTURING THE SAME

(71) Applicant: Wuhan China Star Optoelectronics Semiconductor Display Technology Co., Ltd., Wuhan, Hubei (CN)

(72) Inventor: Chunyang WANG, Wuhan, Hubei (CN)

(21) Appl. No.: 16/339,382

(22) PCT Filed: Nov. 1, 2018
(86) PCT No.: PCT/CN2018/113340

§ 371 Date: Apr. 4, 2019

(51) Int. Cl. H01L 27/32; H01L 51/52; H01L 51/56

(52) U.S. Cl. CPC H01L 27/3246; H01L 27/3258; H01L 51/5209; H01L 27/1248; H01L 51/525; H01L 51/56; H01L 51/5253

(57) ABSTRACT

An organic light emitting diode display and a method for manufacturing the organic light emitting diode display are provided. The display includes a switch array layer, a flatting layer, a conductive layer, a plurality of spaced pixel defining units and a plurality of light emitting units formed on a substrate in sequence. Cross-sectional shapes of the conductive layer and the flatting layer are defined as zigzags. Each light emitting units is formed on the conductive layer formed between two adjacent pixel defining units. The light emitting units are intersected with a horizontal plane.

### CROSS REFERENCE TO RELATED APPLICATION

This application claims the priority of International Application No. PCT/CN2018/113340 filed on 2018 Nov. 1, which claims priority to Chinese Application No. 201811082621.3, filed on 2018 Sep. 17. The entire disclosures of each of the above applications are incorporated herein by reference.

### BACKGROUND OF INVENTION

### Field of Invention

The present invention relates to a field of displays, and particularly to an organic light emitting diode display and a method for manufacturing the organic light emitting diode display.

### Description of Prior Art

The organic light emitting diode (OLED) display panel has been widely used for the advantages of lighter weight, self-illumination, wider viewing angle, lower driving voltage, higher luminous efficiency, lower power consumption and faster response speed.

For a small and medium-sized OLED display panel, the aperture ratio is defined as a ratio of an area of a light emitting area to an area of an entire pixel, as an important parameter and directly related to product performance. The higher aperture ratio can improve the brightness, efficiency and life span of the product.

However, the aperture ratio is limited due to factors such as mask shadow, mask accuracy (Mask PPA), mask line width on the mask (Mask CD), and alignment accuracy during vapor deposition, resulting in a lower aperture ratio.

Therefore, it is necessary to provide an OLED display and a method for manufacturing the OLED to solve the problems of the prior art.

### SUMMARY OF INVENTION

The application mainly provides to an organic light emitting diode display and a method for manufacturing the organic light emitting diode display to improve an aperture ratio.

For the above-mentioned objective, the present disclosure employs the following technical schemes.

The present disclosure provides an organic light emitting diode (OLED) display, includes:

a switch array layer formed on a substrate, wherein the switch array layer includes a plurality of switch elements;

a flat layer formed on the switch array layer, wherein a cross-sectional shape of the flat layer is defined as a zigzag, the flat layer includes a plurality of sawtooth units, a cross-sectional shape of each sawtooth unit is defined as at least one of a triangle or a trapezoid;

a conductive layer formed on the flat layer, wherein a cross-sectional shape of the conductive layer is defined as a zigzag, the conductive layer includes a plurality of anodes;

a pixel defining layer formed on the conductive layer, wherein the pixel defining layer includes a plurality of pixel defining units spaced from each other; and

a plurality of light emitting units formed on the conductive layer formed between two adjacent pixel defining units, wherein the light emitting units are intersected with a horizontal plane, an area of each light emitting unit is greater than a predetermined area.

In the OLED display of one embodiment of the present disclosure, the sawtooth unit includes two oblique sides and a bottom side, and an angle is defined between the oblique side and the bottom side within a predetermined range.

In the OLED display of one embodiment of the present disclosure, each light emitting unit is inclined to the horizontal plane.

In the OLED display of one embodiment of the present disclosure, the conductive layer includes a plurality of protrusions and a plurality of recesses arranged alternately with each other, the pixel defining units are formed on the protrusions and the recesses, the light emitting units are formed between the protrusions and the recesses.

In the OLED display of one embodiment of the present disclosure, two angles are defined between each light emitting unit and the horizontal plane.

In the OLED display of one embodiment of the present disclosure, the conductive layer includes a plurality of protrusions and a plurality of recesses arranged alternately with each other, the pixel defining units are formed on the protrusions or the recesses, the lighting emitting units are formed between two adjacent recesses or between two adjacent protrusions.

In the OLED display of one embodiment of the present disclosure, each pixel defining unit includes a flat top end, and the flat top ends of the pixel defining unit are defined in a same level with each other.

In the OLED display of one embodiment of the present disclosure, further includes a plurality of spacers, a plurality of cathodes, and an encapsulation layer, the spacers are formed on the pixel defining units, the cathodes are formed on the lighting emitting units, and the encapsulation layer is formed at a topmost layer of the OLED display.

The present disclosure also provides an OLED display, includes:

a switch array layer formed on a substrate, wherein the switch array layer includes a plurality of switch elements;

a flat layer formed on the switch array layer, wherein a cross-sectional shape of the flat layer is defined as a zigzag;

a conductive layer formed on the flat layer, wherein a cross-sectional shape of the conductive layer is defined as a zigzag, the conductive layer includes a plurality of anodes;

a pixel defining layer formed on the conductive layer, wherein the pixel defining layer includes a plurality of pixel defining units spaced from each other; and

a plurality of light emitting units formed on the conductive layer formed between two adjacent pixel defining units, wherein the light emitting units are intersected with a horizontal plane.

In the OLED display of one embodiment of the present disclosure, the flat layer includes a plurality of sawtooth units, a cross-sectional shape of each sawtooth unit is defined as at least one of a triangle or a trapezoid.

In the OLED display of one embodiment of the present disclosure, the sawtooth unit includes two oblique sides and a bottom side, and an angle is defined between the oblique side and the bottom side within a predetermined range.

In the OLED display of one embodiment of the present disclosure, an area of each light emitting unit is greater than a predetermined area.

In the OLED display of one embodiment of the present disclosure, each light emitting unit is inclined to the horizontal plane.

In the OLED display of one embodiment of the present disclosure, the conductive layer includes a plurality of protrusions and a plurality of recesses arranged alternately with each other, the pixel defining units are formed on the protrusions and the recesses, the light emitting units are formed between the protrusions and the recesses.

In the OLED display of one embodiment of the present disclosure, two angles are defined between each light emitting unit and the horizontal plane.

In the OLED display of one embodiment of the present disclosure, the conductive layer includes a plurality of protrusions and a plurality of recesses arranged alternately with each other, the pixel defining units are formed on the protrusions or the recesses, the lighting emitting units are formed between two adjacent recesses or between two adjacent protrusions.

In the OLED display of one embodiment of the present disclosure, each pixel defining unit includes a flat top end, and the flat top ends of the pixel defining unit are defined in a same level with each other.

In the OLED display of one embodiment of the present disclosure, further includes a plurality of spacers, a plurality of cathodes, and an encapsulation layer, the spacers are formed on the pixel defining units, the cathodes are formed on the lighting emitting units, and the encapsulation layer is formed at a topmost layer of the OLED display.

The present disclosure also provides a method for manufacturing an OLED display, further including:

forming a switch array layer on a substrate;

forming a flat layer on the switch array layer, patterning the planarization layer to form the planarization layer with a zigzag cross-sectional shape;

forming a conductive layer on the flat layer, patterning the conductive layer to form a plurality of anodes, a conductive layer wherein the conductive layer has a zigzag cross-sectional shape;

forming a pixel defining layer on the conductive layer, patterning the pixel defining layer to form a plurality of pixel defining units spaced from each other; and

forming a light emitting unit on the conductive layer and between each two adjacent pixel defining units.

In the method for manufacturing the OLED display of one embodiment of the present disclosure, after the step of forming a pixel defining layer on the conductive layer, and before the step of forming a light emitting unit on the conductive layer and between each two adjacent pixel defining units, further includes:

forming a photo resist spacer layer on the pixel defining layer, patterning the pixel defining layer and the photo resist spacer layer by a same mask process to form the pixel defining units and a plurality of spacers.

In the organic light emitting diode display and the method for manufacturing the organic light emitting diode display of the present disclosure, the zigzag cross-sectional shape is formed in the flat layer and the light emitting units are intersected with the horizontal plane to increase areas of the light emitting units to be increased, to increase the aperture ratio, and to improve the performance of the display.

### BRIEF DESCRIPTION OF DRAWINGS

FIG. 1 is a schematic view of an OLED display in the prior art.

FIG. 2 is a schematic view of an OLED display of a first exemplary embodiment according to the present disclosure.

FIG. 3 is a schematic view of a flat layer of the OLED display of the present disclosure.

FIG. 4 is a schematic view of a conductive layer of and the OLED display of the present disclosure.

FIG. 5 is a schematic view of an OLED display of a second exemplary embodiment according to the present disclosure.

FIG. 6 is a schematic view of an OLED display of a third exemplary embodiment according to the present disclosure.

### DETAILED DESCRIPTION OF PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, the components having similar structures are denoted by same numerals.

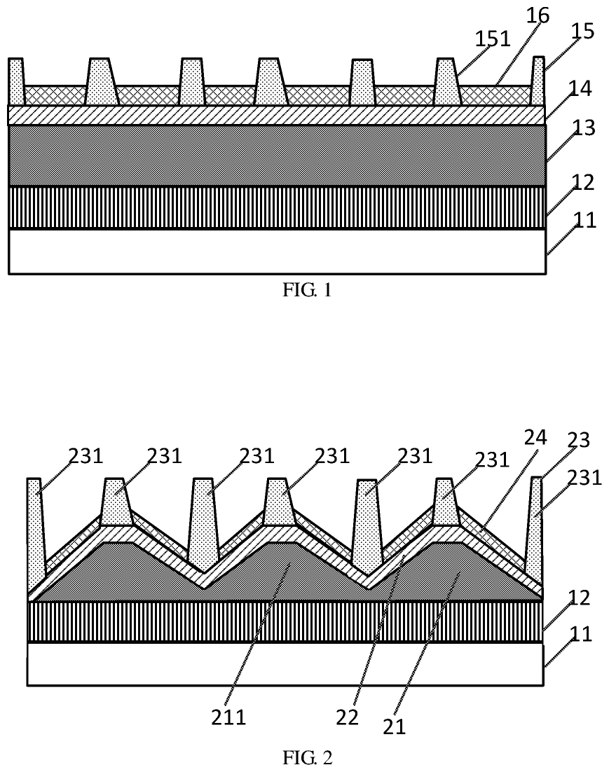

Referring to FIG. 1, an OLED display of the prior art includes a substrate 11, a switch array layer 12, a flat layer 13, a conductive layer 14, a pixel defining layer 15, and a plurality of light emitting units 16. The switch array layer 12 includes a plurality of switch elements, such as thin film transistors. The conductive layer 14 includes a plurality of anodes. The pixel defining layer 15 includes a plurality of pixel defining units 151. A plurality of light emitting units 16 is formed between two adjacent pixel defining units 151, and the light emitting units 16 are paralleled with a horizontal plane.

Referring to FIGS. 2-6, FIG. 2 is a schematic view of an OLED display of a first exemplary embodiment according to the present disclosure.

Referring to FIG. 2, an OLED display of the present disclosure includes a substrate 11, a switch array layer 12, a flat layer 21, a conductive layer 22, a pixel defining layer 23, and a plurality of light emitting units 24. The switch array layer 12 is formed on the substrate 11 and includes a plurality of switch elements, such as thin film transistors.

The flat layer 21 is formed on the switch array layer 12. A cross-sectional shape of the flat layer 21 is defined as a zigzag. In one exemplary embodiment, the zigzag flat layer 21 is formed by a patterning process applied to the flat layer 21 formed on the switch layer 12. The flat layer 21 includes a plurality of sawtooth units 211. A cross-sectional shape of each sawtooth unit 211 is defined as at least one of a triangle or a trapezoid. In one exemplary embodiment, a cross-sectional shape of each sawtooth unit 211 is defined as at least one of an isosceles triangle or an isosceles trapezoid.

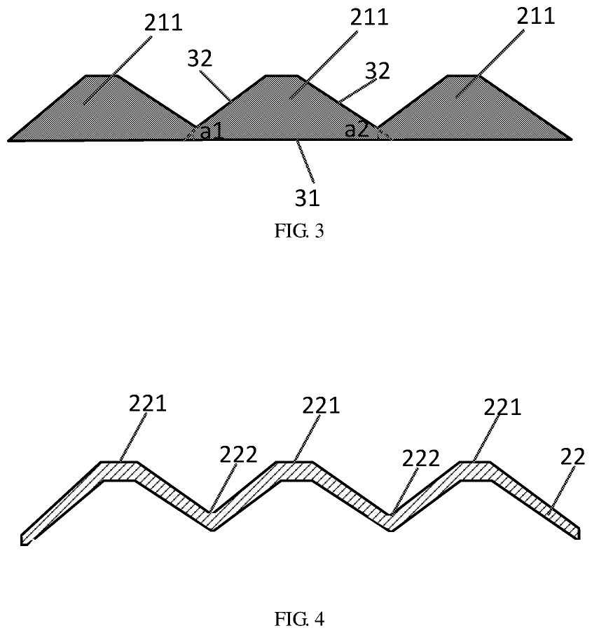

Referring to FIG. 3, each sawtooth unit 211 includes a bottom side 31 and two oblique sides 32. Angles a1 and a2 defined between the oblique sides 32 and the bottom side 31 within a predetermined range. The acute angles of a1 and a2 are defined in a range of 0-90 degrees, and are not equal to 0 degree or 90 degrees. In one exemplary embodiment, the acute angles defined between the oblique sides of the sawtooth units 211 and the horizontal plane are same, such as 40 degrees.

Referring to FIG. 2, a conductive layer 22 is formed on the flat layer 21. The cross-sectional shape of the conductive layer 22 is defined as a zigzag. The conductive layer 22 includes a plurality of anodes. The anodes are connected to the drain electrodes of the thin-film transistors.

A pixel defining layer 23 is formed on the conductive layer. The pixel defining layer 23 includes a plurality of pixel defining units 231 spaced from each other. In one exemplary embodiment, each pixel defining unit 231 includes a flat top end, and the flat top ends of the pixel defining unit 231 are defined in a same level with each other.

A plurality of light emitting units 24 are formed on the conductive layer 22 formed between two adjacent pixel defining units 231. The light emitting units 24 are intersected with a horizontal plane. Comprehensibly, each light emitting unit 24 is located corresponding to each anode.

In one exemplary embodiment, referring to FIG. 2, each light emitting unit 24 is inclined to the horizontal plane. An angle is defined between each light emitting unit 24 and the horizontal plane.

Referring to FIG. 4, the conductive layer 22 includes a plurality of protrusions 221 and a plurality of recesses 222 arranged alternately with each other. The pixel defining units 231 are formed on the protrusions 221 and the recesses 222. The lighting emitting units 24 are formed between the protrusions 221 and the recesses 222.

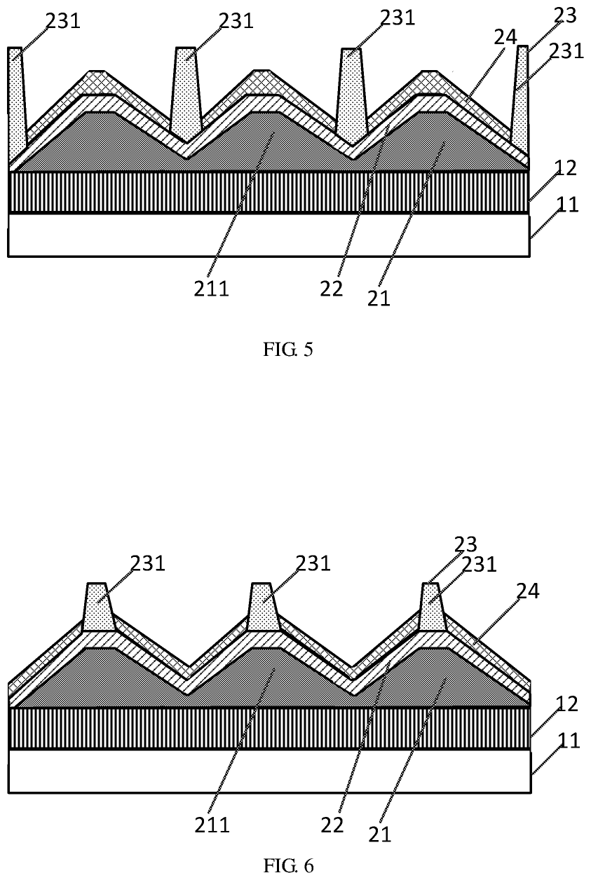

In one exemplary embodiment, referring to FIGS. 4 and 5, two angles are defined between each light emitting unit 24 and the horizontal plane.

The pixel defining units 231 are only defined on the recesses 222. Each light emitting unit 24 is defined between two adjacent recesses 222. A cross-sectional shape of each light emitting unit 24 is defined as a curved.

In the one exemplary embodiment, referring to FIGS. 4 and 6, the pixel defining units 231 are only defined on the protrusions 221. Each light emitting units 24 is defined between two adjacent protrusions 222. A cross-sectional shape of each light emitting unit 24 is defined as a curved.

Since the cross-sectional shape of the flat layer of the present disclosure is defined as a zigzag to make each light emitting unit of the present disclosure to be defined as a inclined or a curved and to make an area of each light emitting unit 24 to be greater than a predetermined area. For example, the predetermined area can be defined as the area of the light emitting unit 24 in FIG. 1. Since the area of each light-emitting unit is increased, and the aperture ratio is increased, and the performance of the display is improved, for example, the brightness, efficiency and life span of the product are improved.

The OLED display of the present disclosure further includes a plurality of spacers, a plurality of cathodes, and an encapsulation layer (not shown). The spacers are defined on the pixel defining units 231. The cathodes are formed on the lighting emitting units 24. The encapsulation layer is formed at a topmost layer of the OLED display.

The present disclosure also provides a method for manufacturing an OLED display, the method includes:

S101, forming a switch array layer on a substrate;

Referring to FIGS. 2, 5, and 6, the substrate is formed on a glass substrate, then the switch array layer 12 is formed on the substrate 11 by an active layer, a first gate insulating layer, a first metal layer, a second gate insulating layer, and a second metal layer form on the substrate 11 in sequency. The second metal layer includes a plurality of source electrodes and a plurality of drain electrodes.

S102, forming a flat layer on the switch array layer, patterning the planarization layer to form the planarization layer with a zigzag cross-sectional shape.

In one embodiment, an entire flat layer is formed on the second metal layer, and then the flat layer is exposed and developed to form a zigzag cross-sectional shape of the flat layer 21. The flat layer can be made of an insulating material.

S103, forming a conductive layer on the flat layer, patterning the conductive layer to form a plurality of anodes, the conductive layer wherein the conductive layer has a zigzag cross-sectional shape.

In one embodiment, the conductive layer 22 is formed on the flat layer 21. The conductive layer 22 has a zigzag cross-sectional shape. The conductive layer 22 is patterned to form a plurality of anodes.

S104, forming a pixel defining layer on the conductive layer, patterning the pixel defining layer to form a plurality of pixel defining units spaced from each other.

In one embodiment, the pixel defining layer 23 is formed on the conductive layer 22. The pixel defining layer 23 is patterned to form a plurality of pixel defining units 231 spaced from each other;

S105, forming a light emitting unit on the conductive layer and between each two adjacent pixel defining units.

In one embodiment, each light emitting unit 24 is formed on the conductive layer 22 formed between each two adjacent pixel defining units 231.

After the step of forming a pixel defining layer on the conductive layer, and before the step of forming a light emitting unit on the conductive layer and between each two adjacent pixel defining units, further includes:

S106, forming a photo resist spacer layer on the pixel defining layer 23, patterning the pixel defining layer 23 and the photo resist spacer layer by a same mask process to form the pixel defining units and a plurality of spacers.

The method further includes: forming a plurality of cathodes on the light emitting units and forming an encapsulation layer on the plurality of spacers and the plurality of cathodes.

In the organic light emitting diode display and the method for manufacturing the organic light emitting diode display of the present disclosure, the zigzag cross-sectional shape is formed in the flat layer and the light emitting units are intersected with the horizontal plane to increase areas of the light emitting units to be increased, to increase the aperture ratio, and to improve the performance of the display.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. An organic light emitting diode (OLED) display, comprising:
a switch array layer formed on a substrate, wherein the switch array layer comprises a plurality of switch elements;
a flat layer formed on the switch array layer, wherein a cross-sectional shape of the flat layer is defined as a zigzag, the flat layer comprises a plurality of sawtooth units, a cross-sectional shape of each sawtooth unit is defined as at least one of a triangle or a trapezoid;
a conductive layer formed on the flat layer, wherein a cross-sectional shape of the conductive layer is defined as a zigzag, the conductive layer comprises a plurality of anodes;
a pixel defining layer formed on the conductive layer, wherein the pixel defining layer comprises a plurality of pixel defining units spaced from each other; and
a plurality of light emitting units formed on the conductive layer formed between two adjacent pixel defining units, wherein the light emitting units are intersected with a horizontal plane, an area of each light emitting unit is greater than a predetermined area.

2. The OLED display of the claim 1, wherein the sawtooth unit comprises two oblique sides and a bottom side, and an angle is defined between the oblique side and the bottom side within a predetermined range.

3. The OLED display of the claim 1, wherein each light emitting unit is inclined to the horizontal plane.

4. The OLED display of the claim 3, wherein the conductive layer comprises a plurality of protrusions and a plurality of recesses arranged alternately with each other, the pixel defining units are formed on the protrusions and the recesses, the light emitting units are formed between the protrusions and the recesses.

5. The OLED display of the claim 1, wherein two angles are defined between each light emitting unit and the horizontal plane.

6. The OLED display of the claim 5, wherein the conductive layer comprises a plurality of protrusions and a plurality of recesses arranged alternately with each other, the pixel defining units are formed on the protrusions or the recesses, the lighting emitting units are formed between two adjacent recesses or between two adjacent protrusions.

7. The OLED display of the claim 1, wherein each pixel defining unit comprises a flat top end, the flat top ends of the pixel defining unit are defined in a same level with each other.

8. The OLED display of the claim 1, wherein further comprises a plurality of spacers, a plurality of cathodes, and an encapsulation layer, the spacers are formed on the pixel defining units, the cathodes are formed on the lighting emitting units, and the encapsulation layer is formed at a topmost layer of the OLED display.

9. An organic light emitting diode (OLED) display, comprising:
a switch array layer formed on a substrate, wherein the switch array layer comprises a plurality of switch elements;
a flat layer formed on the switch array layer, wherein a cross-sectional shape of the flat layer is defined as a zigzag;
a conductive layer formed on the flat layer, wherein a cross-sectional shape of the conductive layer is defined as a zigzag, the conductive layer comprises a plurality of anodes;
a pixel defining layer formed on the conductive layer, wherein the pixel defining layer comprises a plurality of pixel defining units spaced from each other; and
a plurality of light emitting units formed on the conductive layer formed between two adjacent pixel defining units, wherein the light emitting units are intersected with a horizontal plane.

10. The OLED display of the claim 9, wherein the flat layer comprises a plurality of sawtooth units, a cross-sectional shape of each sawtooth unit is defined as at least one of a triangle or a trapezoid.

11. The OLED display of the claim 10, wherein the sawtooth unit comprises two oblique sides and a bottom side, and an angle is defined between the oblique side and the bottom side within a predetermined range.

12. The OLED display of the claim 9, wherein an area of each light emitting unit is greater than a predetermined area.

13. The OLED display of the claim 9, wherein each light emitting unit is inclined to the horizontal plane.

14. The OLED display of the claim 13, wherein the conductive layer comprises a plurality of protrusions and a plurality of recesses arranged alternately with each other, the pixel defining units are formed on the protrusions and the recesses, the light emitting units are formed between the protrusions and the recesses.

15. The OLED display of the claim 9, wherein two angles are defined between each light emitting unit and the horizontal plane.

16. The OLED display of claim 15, wherein the conductive layer comprises a plurality of protrusions and a plurality of recesses arranged alternately with each other, the pixel defining units are formed on the protrusions or the recesses, the lighting emitting units are formed between two adjacent recesses or between two adjacent protrusions.

17. The OLED display of claim 9, wherein each pixel defining unit comprises a flat top end, and the flat top ends of the pixel defining unit are defined in a same level with each other.

18. The OLED display of claim 9, wherein further comprises a plurality of spacers, a plurality of cathodes, and an encapsulation layer, the spacers are formed on the pixel defining units, the cathodes are formed on the lighting emitting units, and the encapsulation layer is formed at a topmost layer of the OLED display.

19. A method for manufacturing an organic light emitting diode (OLED) display, comprising:
forming a switch array layer on a substrate;
forming a flat layer on the switch array layer, patterning the planarization layer to form the planarization layer with a zigzag cross-sectional shape;
forming a conductive layer on the flat layer, patterning the conductive layer to form a plurality of anodes, wherein the conductive layer has a zigzag cross-sectional shape;
forming a pixel defining layer on the conductive layer, patterning the pixel defining layer to form a plurality of pixel defining units spaced from each other; and
forming a light emitting unit on the conductive layer and between each two adjacent pixel defining units.

20. The method for manufacturing the OLED display of claim 19, wherein after the step of forming a pixel defining layer on the conductive layer, and before the step of forming a light emitting unit on the conductive layer and between each two adjacent pixel defining units, further comprises:
forming a photo resist spacer layer on the pixel defining layer, patterning the pixel defining layer and the photo resist spacer layer by a same mask process to form the pixel defining units and a plurality of spacers.
